(19) United States
(12) Patent Application Publication
(10) Pub. No.: US 2011/0068416 A1
(43) Pub. Date: Mar. 24, 2011

(54) SEMICONDUCTOR DEVICE AND METHOD FOR MANUFACTURING THE SAME

(75) Inventor: Yun Ik SON, Seoul (KR)

(73) Assignee: Hynix Semiconductor Inc., Icheon (KR)

(21) Appl. No.: 12/848,005

(22) Filed: Jul. 30, 2010

(30) Foreign Application Priority Data
Sep. 21, 2009 (KR) 10-2009-0088890

(51) Int. Cl. H01L 29/78; H01L 21/336

(52) U.S. Cl. 257/410; 438/305; 257/E21.409; 257/E29.255

(57) ABSTRACT

A semiconductor device and a method for manufacturing the same substantially prevent the degradation of the reliability and characteristics due to hot carriers by using a high-k dielectric material as a gate sidewall spacer material of a gate structure.

### CROSS-REFERENCE TO RELATED APPLICATION

The present application claims priority to Korean patent application number 10-2009-0088890, filed on Sep. 21, 2009, which is incorporated by reference in its entirety.

### BACKGROUND OF THE INVENTION

The present invention relates to a semiconductor device and a method for manufacturing the same.

In the fabrication of transistors for semiconductor devices, one of the most important parameters is the threshold voltage (Vt). The threshold voltage is dependent on a gate oxide film thickness, a channel doping concentration, an oxide charge, and a material used in a gate. As a size of a device is reduced, the threshold voltage deviates from the theoretical value. One of the most controversial problems is a short channel effect which is caused by the reduction of a gate channel length.

As semiconductor devices become more highly integrated, nano-scale devices require elements having a fast speed and a low operating voltage in a range of 1 V to 2 V. Accordingly, a low threshold voltage is required. However, if the threshold voltage is further lowered, it may be impossible to control the device due to the short channel effect. Furthermore, the short channel effect causes a drain induced built-in leakage (DIBL) phenomenon involving hot carriers.

Many studies have been conducted to reduce the short channel effect. However, approaches to meeting the high integration of the semiconductor devices has not been suggested yet.

Although methods of adjusting a doping concentration have been introduced, those methods cannot substantially prevent the short channel effect. Other known methods include a method of forming a super steep retrograde (SSR) channel and an ion implant channel through a vertically abrupt channel doping process, and a method of forming a channel having a halo structure through a laterally abrupt channel doping process and a large angle tilt implant process.

In order to improve the operating characteristics and the short channel effect of the transistors, the method of forming the channel having the halo structure through the increase of a gate dielectric layer and the large angle tilt implant process has been widely used.

However, those methods degrade the reliability and characteristics of devices due to hot carriers.

### BRIEF SUMMARY OF THE INVENTION

In an embodiment of the present invention, a method for manufacturing a semiconductor device includes: forming a gate pattern on a semiconductor substrate; forming a first insulation layer for gate spacer and a second insulation layer for gate spacer on a resulting structure including the gate pattern; forming spacers on sidewalls of the gate pattern by etching the second insulation layer and the first insulation layer; removing the second insulation layer; forming a high-k dielectric material layer on a resulting structure including the first insulation layer; and sequentially forming a nitride layer and an insulation layer on a resulting structure including the high-k dielectric material layer.

The gate pattern may include a gate dielectric layer, a gate electrode layer, and a gate hard mask layer.

The method may further include performing a halo or lightly doped drain (LDD) ion implant process between the forming of the gate pattern and the forming of the first insulation layer and the second insulation layer.

The second insulation layer may be removed by a wet cleaning process using one of HF, buffered oxide etchant (BOE), and a mixture thereof.

The method may further include performing an ion implant process for forming source/drain regions between the forming of the spacers and the removing of the second insulation layer.

The high-k dielectric material layer may include a material selected from the group consisting of nitride, Si₃N₄, ZrO₂, La₂O₃, AlO₂, Ta₂O₅, Gd₂O₃, and a combination thereof.

The insulation layer may be formed of a material selected from the group consisting of boro-phosphor-silicon glass (BPSG), silicon on dielectric (SOD), high density plasma (HDP), and a combination thereof.

In another embodiment of the present invention, a semiconductor device include: a gate pattern formed on a semiconductor substrate; spacers formed on sidewalls of the gate pattern; and a high-k dielectric material layer formed on a resulting structure including the gate pattern.

The gate pattern may include a gate dielectric layer, a gate electrode layer, and a gate hard mask layer.

The high-k dielectric material layer may include a material selected from the group consisting of nitride, HFO, Si₃N₄, ZrO₂, La₂O₃, AlO₂, Ta₂O₅, Gd₂O₃, and a combination thereof.

The semiconductor may further include an insulation layer for spacer on the high-k dielectric material layer.

### BRIEF DESCRIPTION OF THE DRAWINGS

FIGS. 1A to 1I are cross-sectional views illustrating a method for manufacturing a semiconductor device in accordance with an embodiment of the present invention.

### DESCRIPTION OF EMBODIMENTS

Description will now be made in detail with reference to the embodiments of the present invention and accompanying drawings. Wherever possible, the same reference numbers will be used throughout the drawings to refer to the same or like elements.

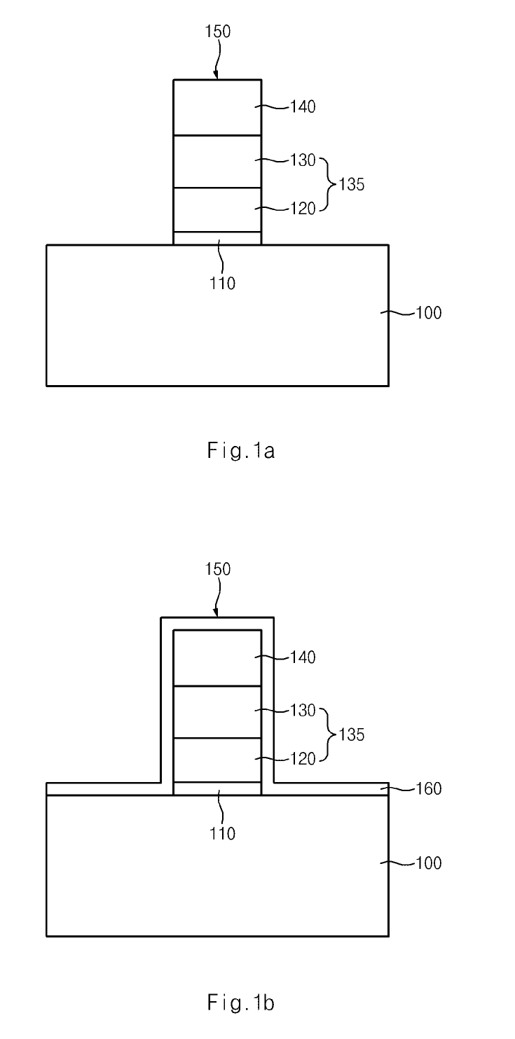

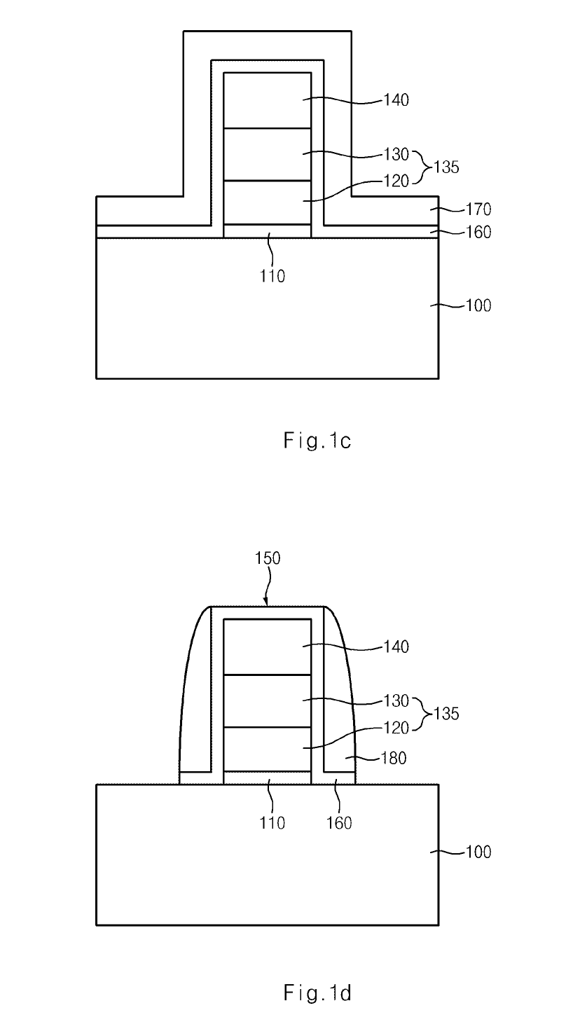

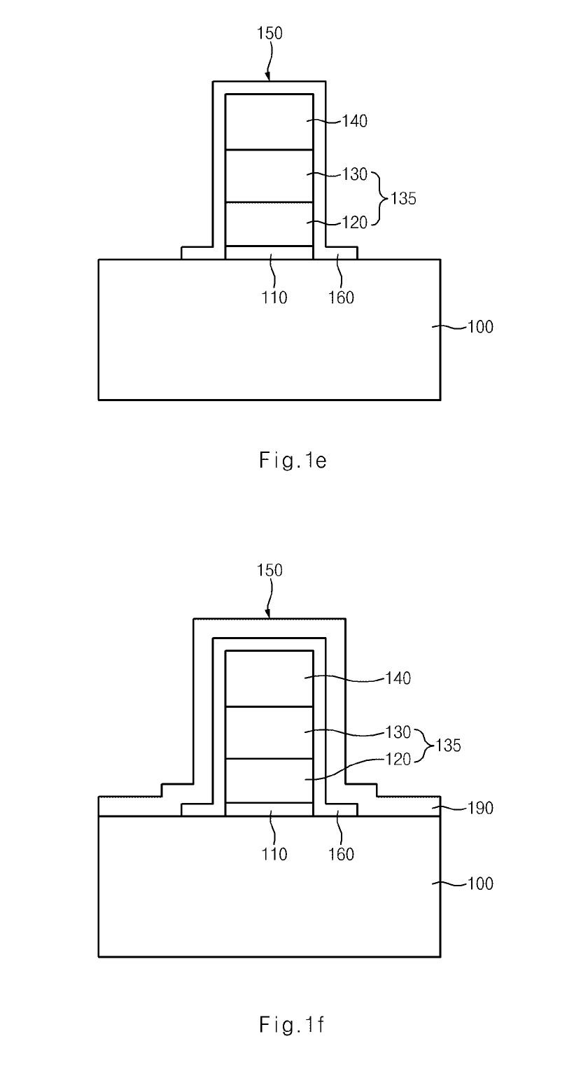

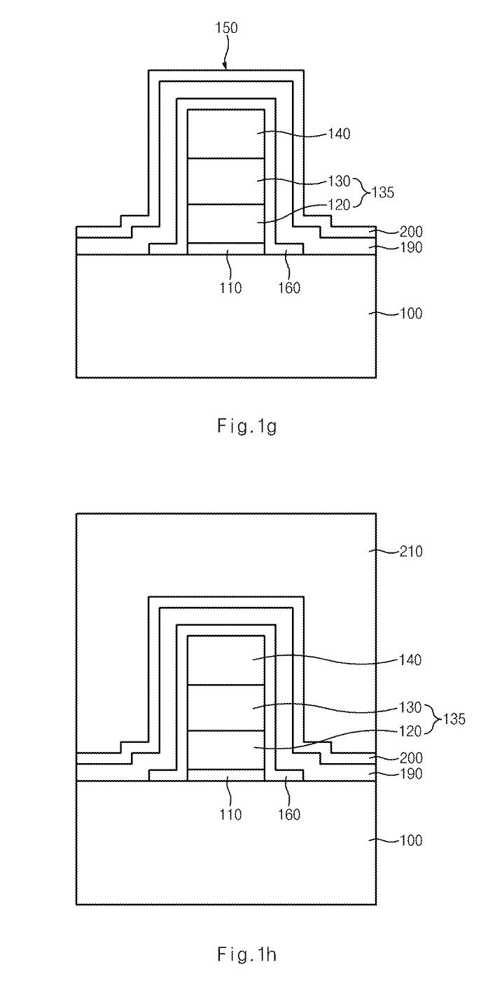

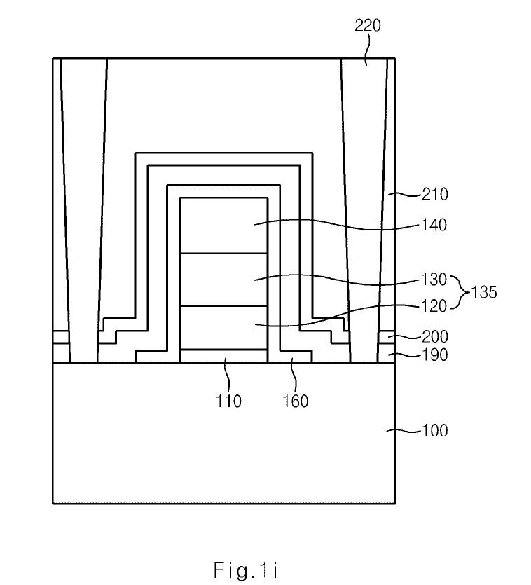

FIGS. 1A to 1I are cross-sectional views illustrating a method for manufacturing transistors in a semiconductor device in accordance with an embodiment of the present invention. The transistors include a cell transistor formed in a cell region and a peripheral transistor formed in a peripheral region of the semiconductor device. FIGS. 1A to 1I illustrate a method for manufacturing the cell transistor, and the description and drawings for the method for manufacturing the peripheral transistor are omitted.

Referring to FIG. 1A, a gate dielectric layer 110, a gate electrode layer 135, and a gate hard mask layer 140 are sequentially stacked on a semiconductor substrate 100. The gate electrode layer 135 has a stack structure including a polysilicon layer 120 and a tungsten layer 130.

A gate pattern 150 is formed by etching the gate hard mask layer 140, the gate electrode layer 135, and the gate dielectric layer 110 using a gate pattern mask (not shown) as an etching mask.

A lightly doped drain (LDD) region (not shown) is formed by implanting impurity ions into the semiconductor substrate 100 exposed under the gate pattern 150.

Referring to FIGS. 1B and 1C, a nitride layer 160 and an oxide layer 170 are sequentially deposited on a resultant structure including the gate pattern 150. Both the nitride layer 160 and the oxide layer 170 are for a gate spacer. At this time, the nitride layer 160 serves as an isolation layer for the LDD region. Also, the oxide layer 170 may include a tetra ethyl ortho silicate (TEOS) layer. The oxide layer 170 thickness is used to adjust the thickness of subsequent sidewall spacers.

Referring to FIG. 1D, spacers 180 are formed on the sidewalls of the gate pattern 150 by etching the oxide layer 170 and the nitride layer 160 until the semiconductor substrate 100 is exposed, wherein the nitride layer 160 and the oxide layer 170 remain on the sidewalls of the gate pattern 150.

Source/drain regions (not shown) are formed by implanting impurity ions into the exposed portions of the semiconductor substrate 100.

Referring to FIG. 1E, the oxide layer 170 of the spacers 180 is removed by performing a wet cleaning process. In this case, the oxide layer 170 of the spacers 180 formed in the peripheral transistor may not be removed. The spacers 180 may be removed by performing a cleaning process using an etching solution selected from the group consisting of HF, buffered oxide etchant (BOE), and a mixture thereof.

Referring to FIG. 1F, a high-k dielectric material layer 190 is formed along a top surface of a resultant structure obtained by removing the oxide layer 170 from the spacers 180. The high-k dielectric material layer 190 may include a material selected from the group consisting of nitride, HFO, Si₃N₄, ZrO₂, La₂O₃, AlO₂, Ta₂O₅, Gd₂O₃, and a combination thereof. Since the high-k dielectric material layer 190 increases a gate fringe field effect, the field is reduced in the source/drain regions (in other words, an electric field crowding effect is alleviated), thereby improving the reliability characteristic with respect to hot carriers.

Referring to FIGS. 1G and 1H, a nitride layer 200 (to be used as a cell spacer) is formed along a resultant structure including the high-k dielectric material layer 190, and then an insulation layer 210 is formed on the nitride layer 200. The nitride layer 200 serves to substantially prevent boron (B) or phosphorus (P) from being diffused to the outside, and the insulation layer 210 serves to alleviate stress between the nitride layer 200 and the semiconductor substrate 100. The insulation layer 210 may be formed of a material selected from the group consisting of boro-phosphor-silicon glass (BPSG), silicon on dielectric (SOD), high density plasma (HDP), and a combination thereof.

Referring to FIG. 1I, a contact region (not shown) is formed by etching the insulation layer 210, the nitride layer 200, and the high-k dielectric material layer 190 until the semiconductor substrate 100 is exposed, by using a contact mask as an etching mask. A contact 220 is formed by filling the contact region with a conductive material.

As described above, the use of the high-k dielectric material as the gate sidewall spacer material of the gate structure makes it possible to substantially prevent the degradation of the reliability and device characteristics due to hot carriers.

The above embodiments of the present invention are illustrative and not limitative. Various alternatives and equivalents are possible. The invention is not limited by the type of deposition, etching, polishing, and patterning steps described herein. Nor is the invention limited to any specific type of semiconductor device. For example, the present invention may be implemented in a dynamic random access memory (DRAM) device or nonvolatile memory device. Other additions, subtractions, or modifications are obvious in view of the present disclosure and are intended to fall within the scope of the appended claims.

What is claimed is:

1. A method for manufacturing a semiconductor device, the method comprising:
forming a gate pattern over a semiconductor substrate;
forming a first insulation layer over the gate pattern and the semiconductor substrate;
forming a second insulation layer over the first insulation layer;
patterning the first and second insulation layers to form a spacer on a sidewall of the gate pattern, the spacer including a first insulation pattern and a second insulation pattern over the first insulation pattern;
forming a high-k dielectric material layer over the first insulation pattern and the semiconductor substrate; and
forming a third insulation layer over the high-k dielectric material layer.

2. The method according to claim 1, wherein the gate pattern comprises a gate dielectric layer, a gate electrode layer, and a gate hard mask layer.

3. The method according to claim 1, further comprising performing a halo or lightly doped drain (LDD) ion implant process on an exposed portion of the semiconductor substrate between the forming of the gate pattern and the forming of the first insulation layer and the second insulation layer.

4. The method according to claim 1, further comprising removing the second insulation pattern of the spacer before the forming of the high-k dielectric material layer, so that the high-k dielectric material is formed directly on the first insulation pattern.

5. The method according to claim 4, wherein the second insulation pattern is removed by performing a wet cleaning process using any one of HF, buffered oxide etchant (BOE), and a mixture thereof.

6. The method according to claim 4, further comprising performing an ion implant process for forming source/drain regions in the semiconductor substrate after the patterning step and before the removing-the-second-insulation-pattern step.

7. The method according to claim 1, wherein the high-k dielectric material layer comprises a material selected from the group consisting of nitride, HFO, Si₃N₄, ZrO₂, La₂O₃, AlO₂, Ta₂O₅, Gd₂O₃, and a combination thereof.

8. The method according to claim 1, further comprising forming a fourth insulation layer over the third insulation layer.

9. The method according to claim 8, wherein the fourth insulation layer is formed of a material selected from the group consisting of boro-phosphor-silicon glass (BPSG), silicon on dielectric (SOD), high density plasma (HDP), and a combination thereof.

10. The method according to claim 1, wherein the third insulation layer is used to form a spacer of a cell transistor in the semiconductor device.

11. The method according to claim 1, wherein the third insulation layer comprises a nitride layer.

12. A semiconductor device comprising:
a gate pattern formed over a semiconductor substrate;
a spacer formed on a sidewall of the gate pattern; and
a high-k dielectric material layer conformally formed over the gate pattern and the semiconductor substrate.

13. The semiconductor device according to claim 12, wherein the gate pattern comprises a gate dielectric layer, a gate electrode layer, and a gate hard mask layer.

14. The semiconductor device according to claim 12, wherein the high-k dielectric material layer comprises a material selected from the group consisting of nitride, HFO, Si₃N₄, ZrO₂, La₂O₃, AlO₂, Ta₂O₅, Gd₂O₃, and a combination thereof.

15. The semiconductor device according to claim 12, further comprising an insulation layer over the high-k dielectric material layer.
